(19) United States
(12) Patent Application Publication
(10) Pub. No.: US 2019/0181611 A1
(43) Pub. Date: Jun. 13, 2019

(54) COMMON MODE NOISE SUPPRESSION OF OPTICAL FREQUENCY COMBS FOR OPTICAL CLOCK APPLICATIONS

(71) Applicant: OEWAVES, INC., PASADENA, CA (US)

(72) Inventors: Lute MALEKI, Pasadena, CA (US); Andrey B. MATSKO, PASADENA, CA (US)

(21) Appl. No.: 16/200,156

(22) Filed: Nov. 26, 2018

Related U.S. Application Data
(60) Provisional application No. 62/596,712, filed on Dec. 8, 2017.

(51) Int. Cl. H01S 5/0687; H01S 3/094; H01S 5/042; G02F 2/02

(52) U.S. Cl. CPC H01S 5/0687; H01S 3/094076; G02F 2203/56; G02F 2/02; H01S 5/0427

(57) ABSTRACT

The disclosure relates in some aspects to a two-point locking system for stabilizing a frequency comb oscillator using at least two optical transitions of the same atomic/molecular sample. In an example, an optical reference sample is provided that is characterized by two or more optical transitions. A coherent light source provides polychromatic coherent light (such as an optical frequency comb). The beams of light, occupying the same spatial mode volume or separated in space, and having frequencies in the vicinity of the optical transitions of the reference sample, interrogate the resonances of the reference sample. Interrogation signals obtained using phase/frequency/amplitude spectroscopy or other spectroscopy techniques are then used to stabilize the frequency harmonics of the light. If the harmonics belong to the same coherent frequency comb, the entire comb becomes stabilized using this procedure. In an illustrative example, a stable atomic optical clock is provided using these techniques.

### PRIORITY CLAIM AND CROSS-REFERENCE TO RELATED APPLICATION

This patent document claims the priority of U.S. Provisional Application No. 62/596,712, entitled “Common Mode Noise Suppression of Optical Frequency Combs for Optical Clock Applications,” filed on Dec. 8, 2017, the entire disclosure of which is incorporated by reference herein.

### FIELD OF THE DISCLOSURE

Various aspects of the disclosure relate to optical metrological devices. More specifically, aspects of the disclosure relate to methods and apparatus for optical clocks and in particular to stabilizing optical frequency combs for optical clock applications.

### BACKGROUND

Stabilized optical comb oscillators can be useful in a variety of metrological applications, including optical atomic clocks. Realization of a completely stabilized equidistant frequency comb oscillator may involve two-point stabilization to stabilize both the center frequency and the free spectral range of the optical comb. This may be characterized, in the time domain, as stabilization of the carrier envelop offset frequency of the comb and the repletion rate of the comb. Often, a first aspect of two-point stabilization involves locking the comb center frequency to an external reference, such as a stabilized cavity or an atomic transition in an optical clock, and the second aspect of the two-point stabilization involves self-locking. Self-locking may be based on a procedure in which the frequency of one of the comb harmonics is coherently multiplied by some number, using a nonlinear optical frequency multiplier, and then compared to another harmonic that is at (or near) the frequency of the multiplied value. Examples of this technique are may be referred to as f-2f and 2f-3f self-referencing. This type of self-referencing may involve generation of broad optical frequency combs covering either an octave (e.g. f-2f self-locking) or ⅔ of an octave (e.g. 2f-3f self-locking). Producing such a comb can be technically complex. Furthermore, spectrally broad frequency combs often consume a lot of power, which is undesirable. It is possible to generate spectrally narrow frequency combs, covering, for example, 1/10 of an octave or less. However, self-referencing does not work very well in such cases. It is also possible to lock two different comb lines to two different atomic clocks. However, the result of such locking may not be optimal. In this regard, the two clocks are often characterized with independent drifts, which are additive if the two harmonics of the comb are locked to the clocks. As a result, the stability of the locked comb can become compromised.

Herein, methods and apparatus are provided to address these or other problems.

### SUMMARY

This document provides, among other features, methods and apparatus that provide two-point locking of frequency combs for use with, e.g., optical atomic clocks.

In one aspect, an apparatus includes: an optical reference sample with first and second optical transitions at different wavelengths; a coherent light source configured to provide polychromatic coherent light, coherent light source optically coupled to the optical reference sample; and a stabilization system configured to provide stabilization of the polychromatic coherent light based on the first and second optical transitions of the reference sample.

In another aspect, a method for generating polychromatic coherent light using a coherent light source; coupling a portion of the polychromatic coherent light into an optical reference sample having first and second optical transitions at different wavelengths; and stabilizing the polychromatic coherent light based on the first and second optical transitions of the reference sample.

In yet another aspect, an apparatus includes: means for generating polychromatic coherent light using a coherent light source; means for coupling a portion of the polychromatic coherent light into an optical reference sample having first and second optical transitions at different wavelengths; and means for stabilizing the polychromatic coherent light based on the first and second optical transitions of the reference sample.

### BRIEF DESCRIPTION OF THE DRAWINGS

FIG. 1 shows an example of an atomic clock system providing two-point locking of a frequency comb based on the D₁ and D₂ optical transitions of rubidium (Rb) atoms confined within a vapor cell.

FIG. 2 shows another example of an atomic clock system providing two-point locking based on optical transitions of Rb atoms confined within a vapor cell.

FIG. 3 illustrates an exemplary method for generating an atomic clock signal while implementing two-point locking.

FIG. 4 summarizes components of an exemplary optical apparatus.

FIG. 5 summarizes further components of an exemplary optical apparatus.

FIG. 6 summarizes an exemplary method according to aspects of the present disclosure.

FIGS. 7A and 7B summarize further aspects of an exemplary method according to the present disclosure.

FIG. 8 illustrates an exemplary processing system that includes an optical atomic clock with two-point locking, such as for use in a portable navigation system.

FIG. 9 summarizes an exemplary general method in accordance with aspects of the present disclosure.

FIG. 10 summarizes an exemplary general apparatus in accordance with aspects of the present disclosure.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. In the figures, elements may each have a same reference number or a different reference number to suggest that the elements represented could be different and/or similar. However, an element may be flexible enough to have different implementations and work with some or all of the systems shown or described herein. The various elements shown in the figures may be the same or different and, which one is referred to as a first element and which is called a second element is arbitrary.

### Overview

Herein, among other aspects, methods and apparatus are described for utilizing a single sample atomic reference for two-point stabilization of an optical frequency comb oscillator for realization of an atomic clock. In an illustrative method, two different optical clock transitions of the same sample of reference atoms or molecules are simultaneously interrogated using two different lasers. Since the reference transitions belong to the same sample, they are influenced by environmental factors in a common manner. As the result, the stability of the relative frequencies of the transitions, expressed as a linear combination m*f1-n*f2 (where m and n are some numbers, and f1 and f2 are the transition frequencies) can be better than the frequency of each transition (f1 and f2) measured separately. Hence, the frequency difference between two optical frequency comb lines that are locked to the two transitions can be stabilized more effectively as compared to locking the frequency comb to two optical sources stabilized to optical transitions produced by two different (e.g. separated in space and/or time) samples of the reference atoms. (Note that, when using the techniques disclosed herein, more than two different optical clock transitions of the same sample of reference atoms/molecules can be interrogated simultaneously to further improve lock quality.)

In the following, to provide concrete examples of these procedures, various atomic clock examples are provided. It should be understood that these are exemplary only, and the general principles described herein may be exploited in a wide variety of methods and apparatus to provide, e.g., for stabilization of polychromatic coherent light. Generally speaking, the beams of the polychromatic coherent light, occupying the same spatial mode volume or separated in space, and having frequencies in the vicinity of the clock transitions of the reference sample, are used to interrogate the resonances of a reference sample that is characterized by two or more optical clock transitions with different wavelengths. Interrogation signals obtained using phase/frequency/amplitude spectroscopy or other techniques may then be used to stabilize the frequency harmonics of the polychromatic coherent light. If the harmonics belong to the same coherent frequency comb, the entire comb becomes stabilized using this procedure.

### Atomic Clock Applications

The development of portable navigation and communication devices has been impeded by a lack of availability of reliable miniature high-performance clocks.

Atomic clocks can operate based on a comparison of the frequency of a local oscillator with a “constant” frequency that corresponds to a transition between two atomic energy levels. Since all atoms of a given species are the same, the same “constant” frequency in a given pair of transitions provides for similar outputs between two clocks made with the same atomic system and architecture. However, atomic transition frequencies are sensitive to local environmental perturbations. For example, atomic clocks based on a transition between hyperfine levels are readily perturbed by an ambient magnetic field, unless adequately shielded. Since the sensitivity to most perturbations encountered by atoms in a vapor cell (or an electrodynamic trap) decrease with increasing transition frequency, optical transitions, with much higher frequency compared to hyperfine transitions, offer greatly reduced sensitivity to perturbations due to collisions, ambient fields, density variations, etc. With the advent of optical frequency combs that relate optical frequencies to radio-frequency (RF) or microwave frequencies, the attributes of optical transitions have been exploited, and optical clocks can provide stable and accurate atomic-based clocks with stabilities and accuracies extending beyond the 10⁻¹⁸ level. This high level of stability and accuracy is achieved, in part, by isolating the atoms undergoing the clock transition and by reducing the sensitivity to perturbations by using techniques such as laser cooling and trapping.

A frequency comb can be used to relate the optical frequency to a countable RF or microwave frequency for use in implementing an optical clock. Optical frequency combs for clock applications may be produced with a mode-locked femtosecond (fs) laser. The repetition frequency (fᵣₑₚ) and the carrier envelope offset frequency (f_{ceo}) of the comb should be stabilized for use as a link between the optical and RF frequencies. Since both the laser frequency (e.g. the center frequency of the comb) and the pulse repetition rate are determined by the same mode-locked laser cavity, they both should be simultaneously stabilized. In other words, the stability of a frequency comb (at least a conventional comb) depends on simultaneously stabilizing the cavity length (⊗r, where r is the cavity length) and the mismatch between the group and phase velocity within the cavity that is caused by dispersion (⊗n, where n is the dispersion). Note that the (electrical) length of the cavity can also depend on the dispersion in the cavity.

Two-point stabilization of the fs mode lock laser can be accomplished by stabilizing the laser frequency to an external laser (itself stabilized to an external cavity and locked to a reference atomic transition) and by implementing so-called 1f to 2f stabilization. (Stabilization of the center frequency of the comb often requires locking it to a stand-alone reference laser; stabilization with the 1f to 2f scheme often requires an octave-spanning comb.)

Despite advances in the realization of ruggedized optical combs based on an fs laser, this style of stabilized comb (involving high enough laser power to generate an octave, a reference laser, and the auxiliary optics and electronics for generation and locking of the 1f to 2f frequency) cannot be easily miniaturized for use in a small atomic clock. However, in the last few years Kerr comb generators based on optical whispering gallery mode (WGM) resonators have become available and are small enough for use in miniature optical clocks.

In the approach described herein, an optical atomic clock is provided by implementing a two-point locking system for stabilization of a frequency comb oscillator and to achieve stabilization of the comb repetition frequency in the microwave domain to the optical frequency. The two-point lock can be implemented, as described herein, using two optical transitions, for example, D₁ and D₂, in rubidium (Rb) atoms confined within the same vapor cell. The use of optical transitions reduces the sensitivity to ambient magnetic fields. The clock sensitivity to ambient perturbations is further reduced since lasers locked to D₁ and D₂ frequency lines of Rb serve to interrogate Rb atoms held in the same vapor cell.

Note that, for convenience herein, frequencies may be occasionally referred to in terms of their corresponding wavelengths. For example, a laser beam within an atomic clock might be referred to as having a frequency of 795 nm. It is meant, of course, that the frequency corresponds to a wavelength of 795 nm. The actual frequency may be expressed in terra Hz (THz). For example, the frequency that corresponds to 795 nm is about 377 THz. The frequency that corresponds to 780 nm is about 384 THz.

### Exemplary Embodiments

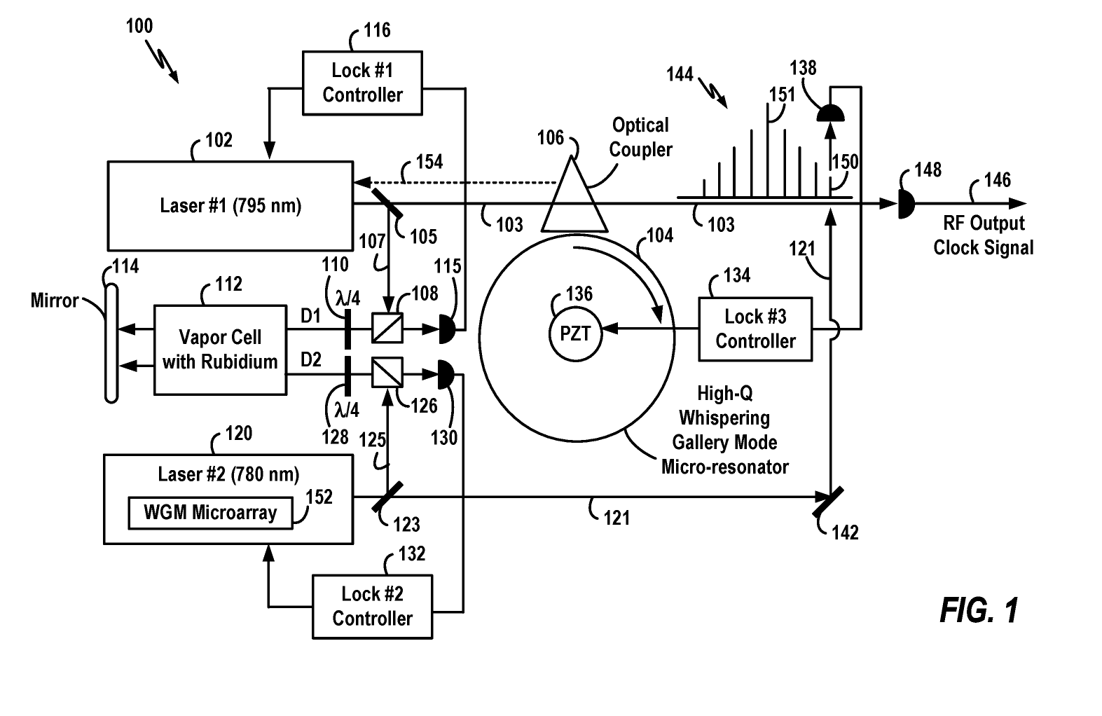

FIG. 1 illustrates an exemplary optical atomic clock 100 for generating an RF clock signal where the optical clock is configured to implement a two-point locking system to stabilization of its frequency comb oscillator.

In the example of FIG. 1, the optical clock includes a 795 nm semiconductor laser (laser #1) 102 that is self-injection locked to a high-Q crystalline whispering gallery mode (WGM) resonator 104 via an optical coupler 106 and is also locked via a Pound-Drever-Hall (PDH) arrangement or sub-system to the D₁ line of Rb held in a vapor cell 112. More specifically, for the D₁ PDH locking, a portion of a main output beam 103 from the 795 nm laser 102 is split off from beam 103 using a beamsplitter 105 as a secondary beam 107 that is directed via a polarization beam splitter (PBS) 108 and a λ/4 plate 110 into a vapor cell 112 that holds one or more Rb atoms, where the beam 107 interrogates the atoms and causes at least some to absorb light at resonant frequency D₁ (which has a corresponding wavelength at or near 795 nm).

A mirror 114 reflects unabsorbed portions of the beam back through the vapor cell 112 to pass through the vapor cell 112 a second time. The reflected beam (showing absorption at frequency D₁) then passes back through a λ/4 plate 110 and PBS 108 to a photodetector 115. (The λ/4 plate 110 and the PBS 108 operate in combination to discriminate between the two directions of light travel, i.e. into and out of the vapor cell 112.) The output electrical signal of the photodetector 115 is applied as feedback to the 795 nm laser 102 via a lock #1 controller 116, which controls and/or modulates the laser 102 based on a D₁ spectroscopic absorption pattern or signal detected by the photodetector 115. In this regard, phase/frequency/amplitude spectroscopy or other suitable spectroscopic techniques may be employed.

The optical clock 100 also includes a 780 nm semiconductor laser (laser #2) 120 that is concurrently locked via PDH to the D₂ line of the Rb held in the vapor cell 106. That is, for the D₂ PDH, a portion of a main output beam 121 from the 780 nm laser 120 is split off from beam 121 using a beamsplitter 123 as a secondary beam 125 that is directed via a PBS 126 and a λ/4 plate 128 into the same vapor cell 112, where the beam interrogates the atoms in the sample and causes at least some to absorb light at resonant frequency D₂ (which is at or near a corresponding wavelength of 780 nm). The mirror 114 again reflects unabsorbed portions of the beam back through the vapor cell 112 to pass through the vapor cell 112 a second time. The reflected beam (showing absorption at frequency D₂) then passes back through a λ/4 plate 128 and PBS 126 to a photodetector 130. The output electrical signal of the photodetector 130 is applied as feedback to the 780 nm laser 102 via a lock #2 controller 132, which controls and/or modulates the laser 102 based on a D₁ spectroscopic absorption pattern or signal detected by the photodetector 130.

As noted, the 795 nm semiconductor laser (laser #1) 102 is also injection locked to the WGM resonator 104 via an optical coupler 106. More specifically, the main portion 103 of the output beam from the 795 nm laser 102 passes through beamsplitter 105 and a portion of beam 103 is then captured by the WGM 104 via coupler 106 (which may be, for example, a prism). The portion of beam 103 captured by the WGM 104 forms propagating waves that resonate therein at frequencies set by a lock #3 controller 134, which controls and/or modulates the WGM 104 using, for example, a lead zirconate titanate (PZT) piezoelectric transducer or actuator component 136 formed within (or on or adjacent to) the WGM 104. The lock #3 controller 134 is controlled by a signal from a photodetector 138 that receives the main portion 121 of the output signal from 780 nm laser 120 that is not split off by beamsplitter 123. As shown, a reflector 142 may be provided to direct the output beam 121 to the photodetector 138. In the illustrative example, the temperature of WGM 104 is set via lock #3 controller 134 and PZT 136 to control the WGM 104. In other examples, the WGM 104 may be controlled and/or modulated by application of an electrical potential and/or mechanical pressure using other types of transducers and/or actuators.

A portion of light from beam 103 that is captured by the WGM 104 then emerges from the WGM as an optical comb. That is, the interaction of the laser 102 and the WGM 104 serves to generate or produce an optical comb within beam 103. (In other examples, the laser 102 may be configured to generate the comb on its own). The optical frequency comb is illustrated in FIG. 1 as comb 144, which is shown adjacent to beam 103 to visually illustrate the polychromatic comb features of beam 103. The comb 144 includes a harmonic 150 at 780 nm and a center frequency 151 with a wavelength corresponding to 795 nm (as well as other harmonics not specifically labeled). In FIG. 1, beam 121 of laser 120 is shown aligned with harmonic 150 to illustrate that the frequency of beam 121 is set to that particular harmonic. One or more periodic beats arise within the optical comb due to interactions between the various frequencies of the comb, such as between the 780 nm harmonic and the 795 nm center line.

Thus, with the overall arrangement of FIG. 1, an electrical signal derived from the 780 nm laser 120 (via photodetector 138) is used to control the characteristics of the WGM 104 (via PZT 136) to modulate the injection locking of the 795 nm laser 102 to stabilize a selected periodic beat in the optical comb 141 of beam 103, where a periodicity of the beat is based, e.g., on a difference in frequency between the harmonic 150 and the center frequency 151 of the comb 144 (or between any other two harmonics). The beat in beam 103 is detected by a fast photodetector 148, which outputs an RF clock signal based on the beat. Although not shown in FIG. 1, additional circuitry may be provided to convert (e.g. rectify) the output from the photodetector 148, which may be sinusoidal, into a clock signal with sharp rising and falling clock pulse edges.

Hence, a signal derived from beam 121 (which is PDH locked to the D₂ line of the Rb and hence to the harmonic 150 of the optical comb 144) is used to stabilize a beat within the optical comb 141 of beam 103 (which is PDH locked to the D₁ line of the Rb and hence to the center frequency 151 of the optical comb 144). Thus, two-point locking of the comb is provided (via D₁ and D₂ of the Rb atomic reference sample) to stabilize the optical comb 144 and thus also stabilize the final clock signal 146.

In this manner, two beams of the light (from the first and second lasers) that occupy the same spatial mode volume (or are separated in space) and have frequencies in the vicinity of the clock transitions of the reference sample are used to interrogate the resonances of the reference sample. The interrogation signals obtained with phase/frequency/amplitude spectroscopy or other spectroscopy techniques are used to stabilize the frequency harmonics of the light. If the harmonics belong to the same coherent frequency comb, the entire comb becomes stabilized because of this procedure.

Note that, as shown in FIG. 1, the 780 nm laser 120 may include, or be coupled to, a WGM microcavity 152 (which is separate from the WGM 104) that provides self injection locking of laser 120. The WGM microcavity 152 may include a piezo element (not separately shown) that is controlled based on the signal from the lock #2 controller 122. The WGM microcavity 152 may be configured to provide low residual amplitude modulation and linewidth reduction of the 780 nm laser 120.

Note also that some resonant Rayleigh scattering occurs in the WGM resonator 104 due, e.g., to surface and volumetric inhomogeneities, which is reflected back to 795 nm laser 102, as indicated by backscattered beam 154. In this regard, some amount of light reflects back into the laser 102 when the frequency of the emitted light coincides with the frequency of a resonator mode of WGM 104, providing optical feedback, which can lead to a reduction of laser linewidth of the 795 nm laser 102. Similar Rayleigh scattering may occur in the WGM microcavity 152 to provide a backscattered beam (not shown) to the 780 nm laser to provide similar optical feedback.

The following paragraphs highlight and discuss other notable features of the apparatus and configuration of FIG. 1.

The PDH locks of lasers 102 and 120 to the D₁ and D₂ lines, respectively, are primarily accomplished by modulating, controlling or adjusting the corresponding WGM resonator (104 or 152) via a suitable piezo element, and not the laser current. This modulation scheme can provide quite low (e.g. −80 dB) relative amplitude modulation (RAM) since it produces pure frequency modulated signals. As a consequence, the lasers 102 and 120 can be locked to the Rb lines to achieve long-term stability better than, e.g., 10⁻¹³. This stabilization scheme can also feature ultra-narrow linewidths because of the injection locking to, e.g., the high-Q crystalline resonator 104.

The laser stabilization to the D₁ Rb line serves to stabilize the fₙ=N_{frep}+f_{ceo} harmonic of the frequency comb 144, and the second laser 120 locked to the D₂ line stabilizes the fₘ=M_{frep}+f_{ceo} of the comb. Since integer M is known, by utilizing the lock D₁, the apparatus of FIG. 1 thus stabilizes both fᵣₑₚ and f_{ceo}.

Stabilization to the D₁ and D₂ lines of Rb held in the same cell may serve to ensure that the relative stability of the two locks can be as high as, e.g., 10⁻¹⁵, since all perturbations to the atoms held in the cell, at least to first order, are the same for both transitions. This is because of near equality of collision cross sections, magnetic sensitivity, and quadratic Stark shift of energy levels for D₁ and D₂ transitions, as they originate in the same ground state, and the excited state transition energies (frequencies) are very close.

Generation of the optical comb 144 (which may be a normal group velocity dispersion (GVD) Kerr frequency comb) may exploit an ultra-high Q crystalline (CaF₂) resonator for use as WGM 104. Since the threshold for comb generation is related to the inverse square of the Q of the resonator, power requirements can be quite modest. Combs with as little as 5 milliWatt (mW) may be generated in this manner at 795 nm. As such, the optical clock 100 may have modest power requirements for operation.

The configuration of FIG. 1 also allows for generating a comparably spectrally narrow frequency comb that spreads from 795 nm to 780 nm. As such, there is no need to reach octave spreading of the frequency comb (which might be challenging at these wavelengths, where the GVD is normal).

The optical clock 100 can be readily packaged in a miniature package for a wide variety of practical applications.

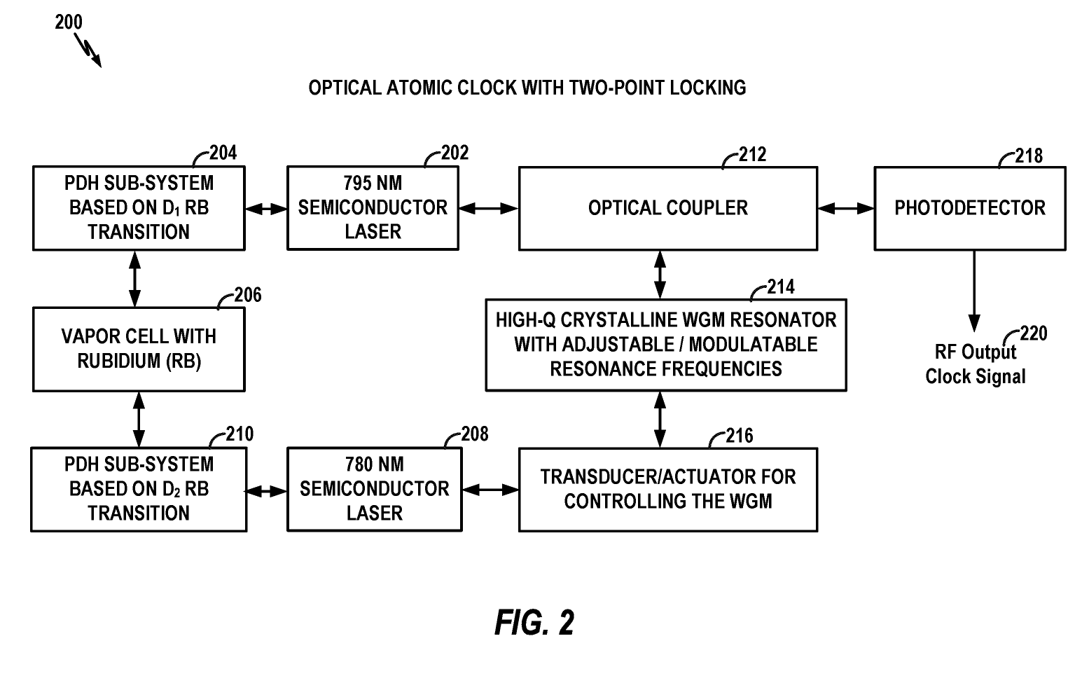

FIG. 2 summarizes an optical atomic clock 200 with two-point locking. The clock may employ the various components of the exemplary apparatus of FIG. 1 or may use other suitably-equipped devices or components. A 795 nm semiconductor laser 202 is coupled to a PDH sub-system 204 that is configured to operate based on the D₁ Rb transition of one or more rubidium atoms held within a vapor cell 206 (or other suitable containment system). A 780 nm semiconductor laser 208 is coupled to a separate PDH sub-system 210 that is configured to operate based on the D₂ Rb transition of the one or more rubidium atoms held within the same vapor cell 206. The D₁ and D₂ PDH sub-systems 204 and 210 operate to lock respective lasers 202 and 208 (as described above).

The 795 nm laser 202 is also coupled via an optical coupler 212 to a high-Q crystalline WGM resonator 214 with adjustable/modulatable resonance frequencies. That is, a portion of a laser beam output from the 795 nm laser 202 is coupled into the WGM resonator 214, and propagates and resonates therein, which serves to provide injection locking of the 795 nm laser 202 and also generates the optical comb. The 780 nm laser 208 is also coupled via a transducer/actuator 216 to the same high-Q WGM resonator 214 to adjust and/or modulate at least one of its resonance frequencies. Note that, whereas the coupling of the 795 nm laser beam into the WGM resonator 214 is an optical coupling via a prism or the like, the coupling of the 780 nm laser beam to the WGM resonator 214 is instead achieved, as described above, by deriving an electrical signal from the 780 nm laser beam, which is then used to control the transducer/actuator 216 (e.g. PZT) by applying mechanical, thermal, or electrical signals to the WGM resonator 214 to modulate one or more of its resonance frequencies. The effect of modulating the WGM resonator 214 using the 780 nm laser output is to stabilize beats with selected frequencies or periodicities within an optical comb emerging from the WGM 214. A photodetector 218 or other suitable device detects the periodic beats within the optical comb and generates an RF clock signal 220 as output.

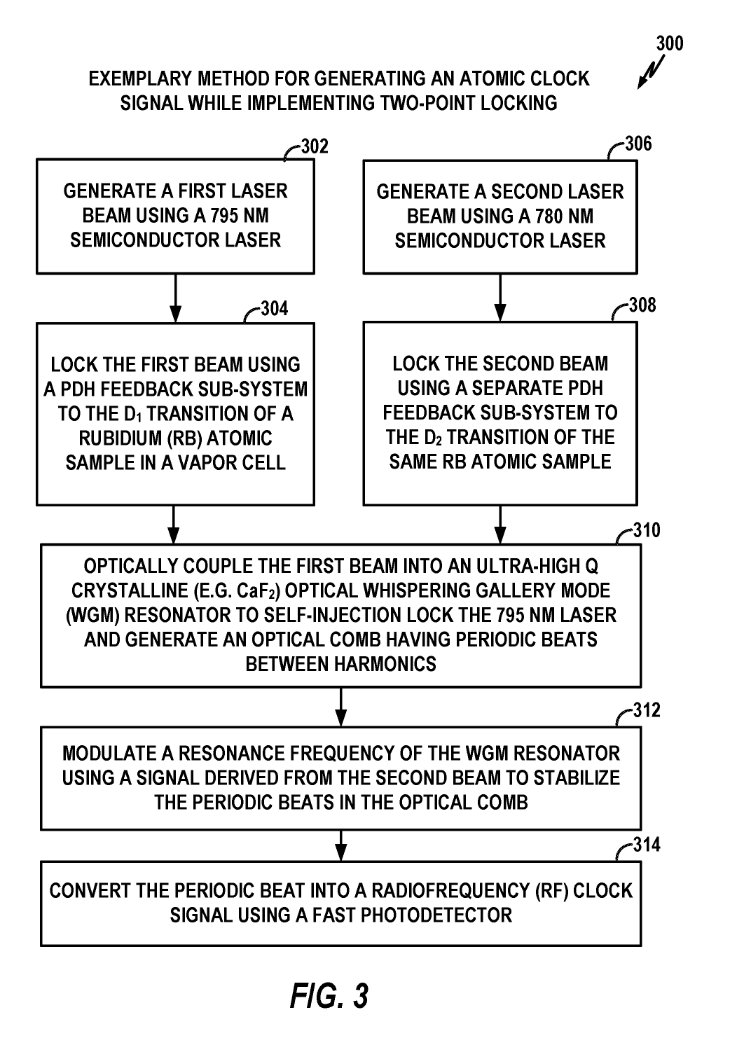

FIG. 3 illustrates a method 300 for generating an atomic clock signal while implementing a two-point locking and stabilization system. The method may employ the apparatus of FIG. 1 or other suitably-equipped devices or apparatus.

Beginning at block 302 of FIG. 3, the optical clock apparatus generates a first laser beam using a 795 nm semiconductor laser. At block 304, the optical clock apparatus locks the first beam using a PDH feedback sub-system to the D₁ transition of a rubidium (Rb) atomic sample in a vapor cell. Concurrently, beginning at block 306, the optical clock apparatus generates a second laser beam using a 780 nm semiconductor laser and, at block 308, locks the second beam using a separate PDH feedback system to the D₂ transition of the same Rb atomic sample.

At block 310, the optical clock apparatus optically couples the first beam into an ultra-high Q crystalline (e.g. CaF₂) optical WGM resonator to self-injection lock the 795 nm laser and generate an optical comb having periodic beats between harmonics. At block 312, the optical clock apparatus modulates a resonance frequency of the WGM resonator using a signal derived from the second laser beam to stabilize the periodic beats in the optical comb and complete the two-point locking of the optical comb. At block 314, the optical clock apparatus converts the periodic beats within the beam emerging from the resonator into a RF clock signal using a fast photodetector.

### Additional Embodiments

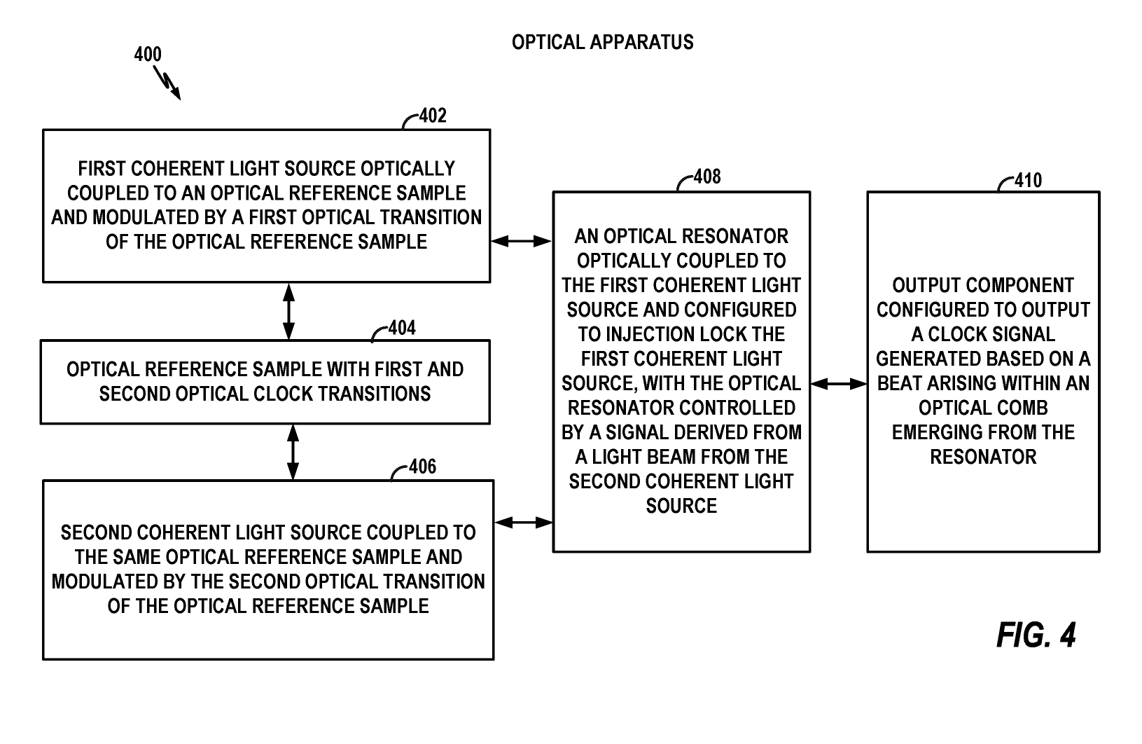

FIG. 4 summarizes features of an exemplary apparatus 400. Briefly, a first coherent light source 402 is optically coupled to an optical reference sample 404 and modulated by a first optical transition of the optical reference sample 404. The optical reference sample 404 has at least first and second optical clock transitions. A second coherent light source 406 is coupled to the same optical reference sample 404 and modulated by the second optical transition of the optical reference sample 404. An optical resonator 408 is optically coupled to the first coherent light source 402 and configured to injection lock the first coherent light source 402, with the optical resonator 408 controlled by a signal derived from a light beam from the second coherent light source 406. In the example of FIG. 4, an output component 410 is also provided that is configured to output a clock signal generated based on one or more beats arising within an optical comb emerging from the optical resonator 408.

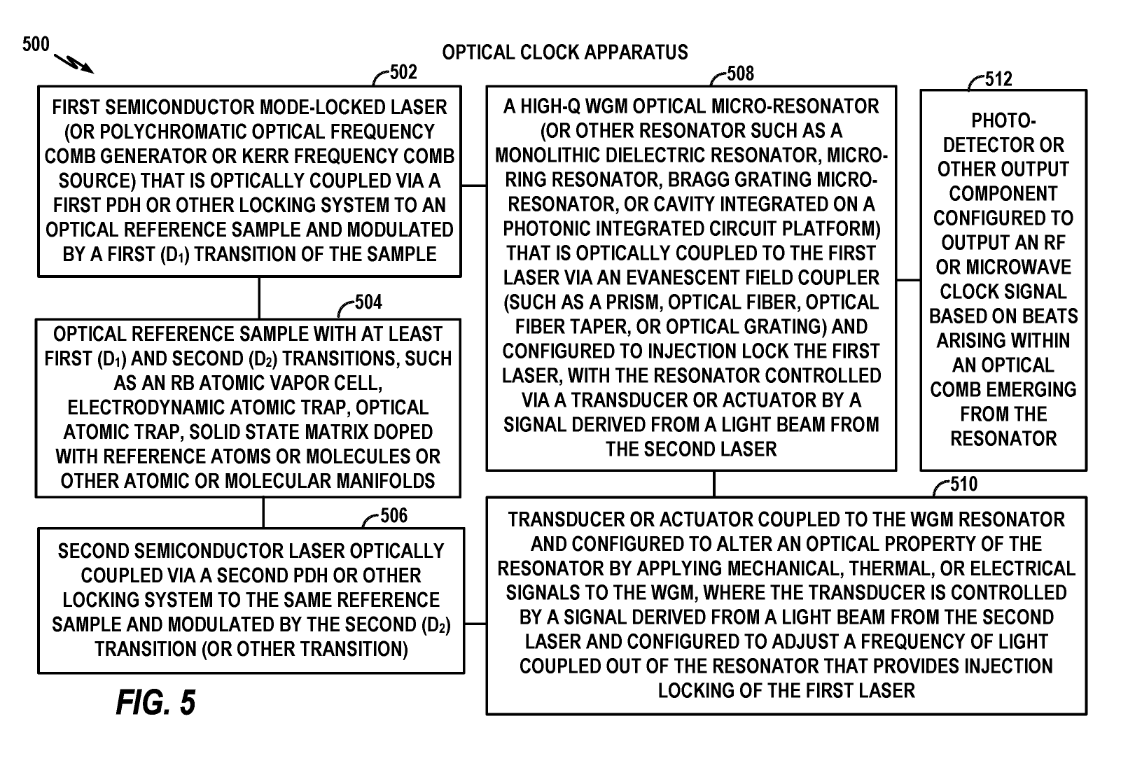

FIG. 5 summarizes additional features of an exemplary optical clock apparatus 500 for generating a clock signal. The clock apparatus 500 includes a first semiconductor mode-locked laser 502 (or optical polychromatic frequency comb generator or Kerr frequency comb source) that is optically coupled via a first PDH or other locking system to an optical reference sample 504 and modulated by a first (D₁) transition of the sample. The optical reference sample 504 has at least first (D₁) and second (D₂) transitions, such as an Rb atomic vapor cell, electrodynamic atomic trap, optical atomic trap, solid state matrix doped with reference atoms or molecules, or other atomic or molecular manifolds. A second semiconductor laser 504 (or other coherent light source) is optically coupled via a second PDH or other locking system to the same reference sample 504 and modulated by the second (D₂) transition (or other suitable transition).

The clock apparatus 500 also includes a high-Q WGM optical micro-resonator 508 (or other resonator such as a monolithic dielectric resonator, micro-ring resonator, Bragg grating micro-resonator, or cavity integrated on a photonic integrated circuit platform) that is optically coupled to the first laser 502 via an evanescent field coupler (such as a prism, optical fiber, optical fiber taper, or optical grating) and configured to injection lock the first laser 502, with the resonator 508 controlled via a transducer or actuator 510 by a signal derived from a light beam from the second laser 506. That is, a transducer or actuator 510 is coupled to the WGM resonator 508 and configured to alter an optical property of the resonator by applying mechanical, thermal, and/or electrical signals to the WGM, where the transducer is controlled by a signal derived from a light beam from the second laser 506 and configured to adjust a frequency of light coupled out of the resonator 508 that provides injection locking of the first laser 502. A photo-detector or other output component 512 is configured to output an RF or microwave clock signal based on one or more beats arising within an optical comb emerging from the WGM resonator 508 (which, as already explained, may arise between a center frequency and a harmonic of the optical comb or between two or more harmonics).

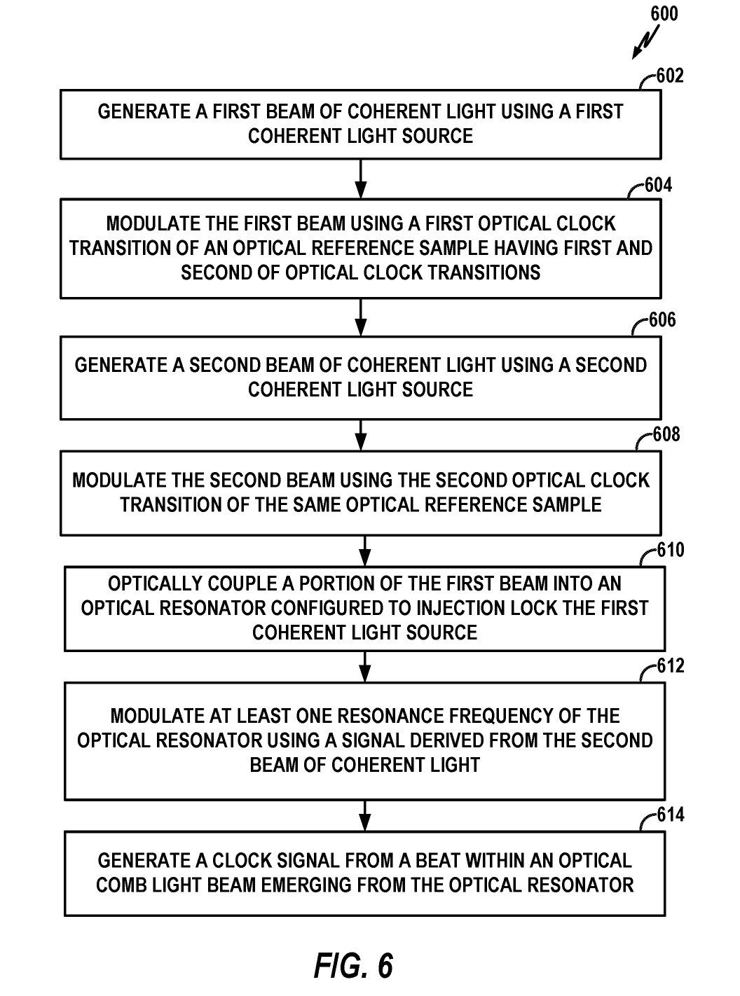

FIG. 6 summarizes features of an exemplary method 600 for generating a clock signal using an optical apparatus. Briefly, at block 602, the apparatus generates a first beam of coherent light using a first coherent light source. At block 604, the apparatus modulates the first beam using a first optical clock transition of an optical reference sample having first and second of optical clock transitions. At block 606, the apparatus generates a second beam of coherent light using a second coherent light source. At block 608, the apparatus modulates the second beam using the second optical clock transition of the same optical reference sample. At block 610, the apparatus optically couples a portion of the first beam into an optical resonator configured to injection lock the first coherent light source. At block 612, the apparatus modulates at least one resonance frequency of the optical resonator using a signal derived from the second beam of coherent light. At block 614, the apparatus generates a clock signal from a beat within an optical comb light beam emerging from the optical resonator.

In at least some examples, means may be provided for performing the functions illustrated in FIG. 6 and/or other functions illustrated or described herein. For example, the means may include one or more of: means, such as light source 402 of FIG. 4, for generating a first beam of coherent light using a first coherent light source; means, such as PDH sub-system 204 of FIG. 2, for modulating the first beam using a first optical transition of an optical reference sample having first and second of optical transitions; means, such as light source 406 of FIG. 4, for generating a second beam of coherent light using a second coherent light source; means, such as PDH sub-system 210 of FIG. 2, for modulating the second beam using the second optical clock transition of the same optical reference sample; means, such as optical coupler 212 of FIG. 2, for optically coupling a portion of the first beam into an optical resonator configured to injection lock the first coherent light source; means, such as transducer 216 of FIG. 2, for modulating at least one resonance frequency of the optical resonator using a signal derived from the second beam of coherent light; and means, such as photodetector 218, for generating a clock signal from a beat within an optical comb light beam emerging from the optical resonator.

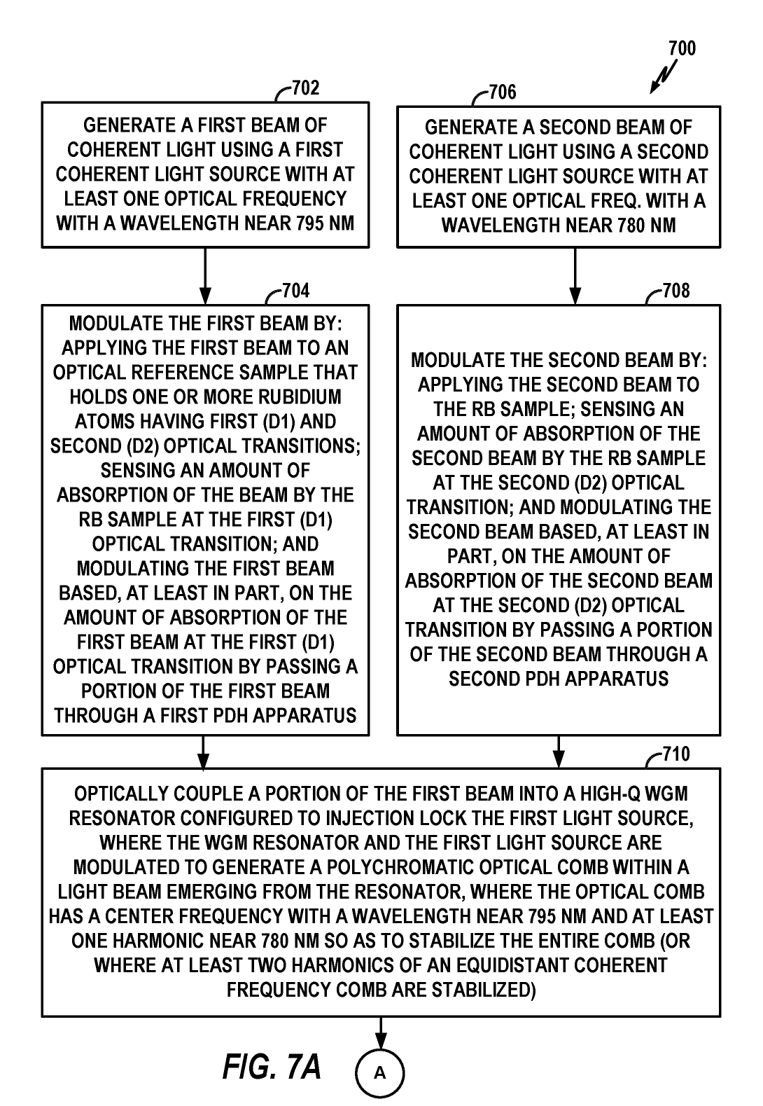

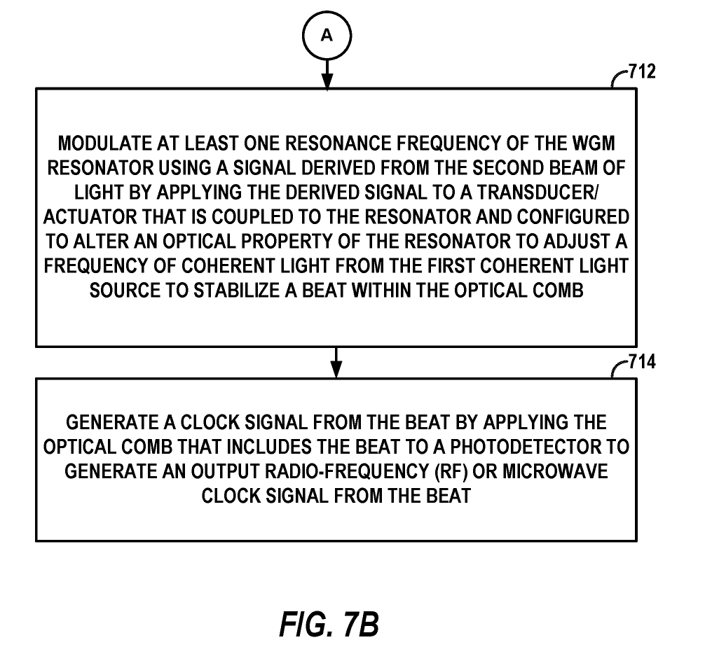

FIGS. 7A and 7B illustrate additional features of an exemplary method for generating a clock signal using an apparatus. In particular, the exemplary method 700 of FIGS. 7A and 7B illustrates various more specific procedures and sub-procedures for use with an apparatus that includes a WGM resonator and an Rb sample. Beginning at block 702 of FIG. 7A, the apparatus generates a first beam of coherent light using a first coherent light source with at least one optical frequency with a wavelength near 795 nm. At block 704, the apparatus modulates the first beam by: applying the first beam to an optical reference sample that holds one or more rubidium atoms having first (D₁) and second (D₂) optical transitions; sensing an amount of absorption of the beam by the Rb sample at the first (D₁) optical transition; and modulating the first beam based, at least in part, on the amount of absorption of the first beam at the first (D₁) optical transition by passing a portion of the first beam through a first PDH apparatus.

Concurrently or simultaneously, beginning at block 706, the apparatus generates a second beam of coherent light using a second coherent light source with at least one optical frequency with a wavelength near 780 nm. At block 708, the apparatus modulates the second beam by: applying the second beam to the Rb sample; sensing an amount of absorption of the second beam by the Rb sample at the second (D₂) optical transition; and modulating the second beam based, at least in part, on the amount of absorption of the second beam at the second (D₂) optical transition by passing a portion of the second beam through a second PDH apparatus.

At block 710, the apparatus optically couples a portion of the first beam into a high-Q WGM resonator configured to injection lock the first light source, where the WGM resonator and the first light source are modulated to generate an optical comb within a light beam emerging from the resonator, and where the optical comb has a center frequency with a wavelength near 795 nm and at least one harmonic near 780 nm so as to stabilize the entire comb (or where at least two harmonics of an equidistant coherent frequency comb are stabilized).

At block 712 of FIG. 7B, the apparatus modulates at least one resonance frequency of the WGM resonator using a signal derived from the second beam of light by applying the derived signal to a transducer/actuator that is coupled to the resonator and configured to alter an optical property of the resonator to adjust a frequency of coherent light from the first coherent light source to stabilize a beat within the optical comb (where the beat may be based, e.g., on a difference between the 780 nm harmonic and the 795 nm center wavelength of the optical comb, i.e. the beat arises between at least two frequencies of the optical comb emerging from the optical resonator). At block 714, the apparatus generates a clock signal from the beat by applying the optical comb that includes the beat to a photodetector to generate an output RF or microwave clock signal from the beat.

In at least some examples, means may be provided for performing the functions illustrated in FIGS. 7A and 7B and/or other functions illustrated or described herein. Exemplary apparatus or components corresponding to the various means are discussed and described above and will not be specifically listed in the following. The means may include one or more of: means for generating a first beam of coherent light using a first coherent light source with at least one optical frequency with a wavelength near 795 nm; means for modulating the first beam, including means for applying the first beam to an optical reference sample that holds one or more rubidium atoms having first and second optical transitions, means for sensing an amount of absorption of the beam by the Rb sample at the first optical transition, and means for modulating the first beam based, at least in part, on the amount of absorption of the first beam at the first (optical transition by passing a portion of the first beam through a first PDH apparatus.

The means may include one or more of: means for generating a second beam of coherent light using a second coherent light source with at least one optical freq. with a wavelength near 780 nm; means for modulating the second beam, including means for applying the second beam to the Rb sample, means for sensing an amount of absorption of the second beam by the Rb sample at the second optical transition, and means for modulating the second beam based, at least in part, on the amount of absorption of the second beam at the second optical transition by passing a portion of the second beam through a second PDH apparatus; means for optically coupling a portion of the first beam into a high-Q WGM resonator configured to injection lock the first light source, where the WGM resonator and the first light source are modulated to generate a polychromatic optical comb within a light beam emerging from the resonator; means for modulating at least one resonance frequency of the WGM resonator using a signal derived from the second beam of light to stabilize a beat within the optical comb (where the beat may be based, e.g., on a difference between the 780 nm harmonic and the 795 nm center wavelength of the optical comb); and means for generating a clock signal from the beat by applying the optical comb that includes the beat to a photodetector to generate an output RF or microwave clock signal from the beat.

In some examples, the clock may be a component of a processing system, such as the processing system of a portable navigation or communication device.

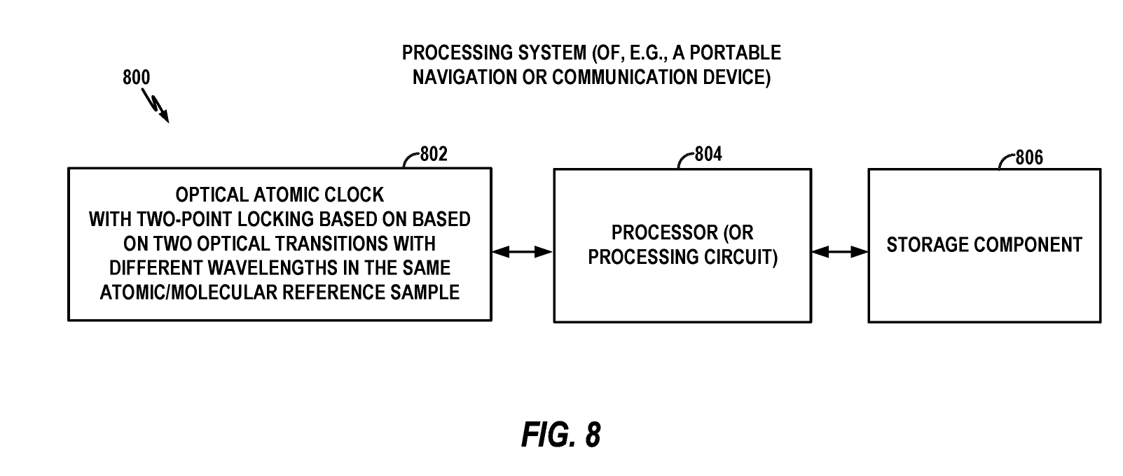

An exemplary processing system 800 of, e.g., a portable navigation or communication device is illustrated in FIG. 8. Briefly, the system 800 includes: an optical atomic clock 802 with two-point locking based on two optical transitions with different wavelengths in the same atomic/molecular reference sample, such as the optical clocks discussed above; a processor or processing circuit 804 (e.g., at least one processor, processing component, and/or other suitable circuitry); and a storage component 806 for storing data and/or programming instructions or other information. These components may communicate with one another via signaling busses or the like, not shown in FIG. 8. Note that other components, such as peripherals, voltage regulators, and power management circuits, may also be employed, though not shown. Also, other components of the portable navigation or communication device, such as suitable radio transceivers, antennae, etc., are not shown.

The storage medium 806 may be, for example, a computer-readable, machine-readable, and/or processor-readable device for storing programming, such as processor-executable code or instructions (e.g., software or firmware), electronic data, databases, or other digital information. The storage medium 806 may also be used for storing data used by the processing circuit 804 when executing programming. The storage medium 806 may be any available media accessible by a general purpose or special purpose processor, including portable or fixed storage devices, optical storage devices, and various other mediums capable of storing, containing or carrying programming. The storage medium 806 may include, e.g., a magnetic storage device (e.g., hard disk, floppy disk, magnetic strip), an optical disk (e.g., a compact disc (CD)), a smart card, a flash memory device, a random access memory (RAM), read only memory (ROM), programmable ROM (PROM), electrically programmable ROM (EPROM), etc., or any other suitable medium for storing software and/or instructions. The storage medium 806 may be embodied in an article of manufacture (e.g., a computer program product). The computer program product may include a computer-readable medium in packaging materials. In some implementations, the storage medium 806 is a non-transitory (e.g., tangible) storage medium. For example, the storage medium 806 may be a non-transitory computer-readable medium storing computer-executable code, including code to perform various operations as described herein. Programming stored by the storage medium 806, when executed by the processing circuit 804, causes the processing circuit 804 to perform one or more of the various functions and/or process operations described herein.

The processing circuit 804 may be generally adapted or configured for executing programming stored on the storage medium 806. As used herein, the terms “code” or “programming” include instructions, instruction sets, data, code, code segments, program code, programs, programming, subprograms, software modules, applications, software applications, software packages, routines, subroutines, objects, executables, threads of execution, procedures, functions, etc., whether referred to as software, firmware, microcode, hardware description language, or otherwise.

The processing circuit 804 may include circuitry configured to implement desired programming provided by appropriate media. For example, the processing circuit 804 may be implemented as one or more processors, one or more controllers, and/or other structure configured to execute executable programming. Examples of the processing circuit 804 may include a general-purpose processor, a digital signal processor (DSP), an application-specific integrated circuit (ASIC), or other programmable logic component, etc., or any combination thereof designed to perform the functions described herein. A general-purpose processor may include a microprocessor, as well as any conventional processor, controller, microcontroller, or state machine. The processing circuit 804 may be implemented as a combination of computing components, such as a controller and a microprocessor, or other varying configurations. These examples are for illustration and other suitable configurations within the scope of the disclosure are also contemplated. The processing circuit 804 may be adapted to control or perform any or all of the features, processes, functions, operations and/or routines for any or all of the apparatuses or devices described herein. As used herein, the term “configured” in relation to the processing circuit 804 may refer to the processing circuit 804 being one or more of adapted, employed, implemented, and/or programmed to perform a particular process, function, operation and/or routine according to various features described herein.

### Summary of General Features and Embodiments

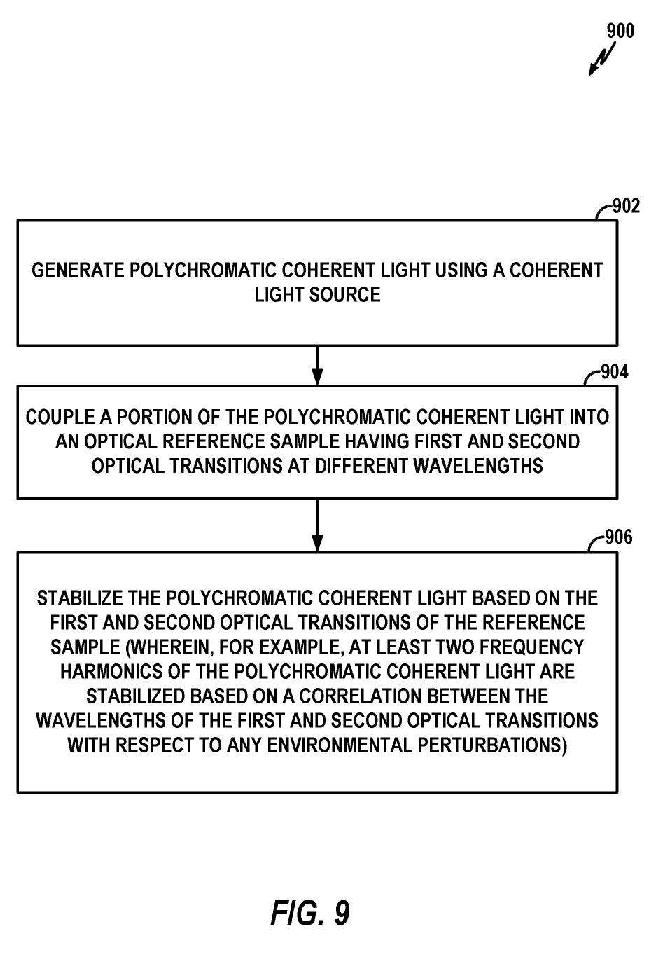

FIG. 9 summarizes general features of an exemplary method 900 that may be used to, for example, stabilize a frequency comb oscillator using at least two optical transitions of the same atomic/molecular sample. Briefly, at block 902, a suitably-equipped apparatus generates polychromatic coherent light using a coherent light source. At block 904, the apparatus couples a portion of the polychromatic coherent light into an optical reference sample having first and second optical transitions at different wavelengths. At block 906, the apparatus stabilizes the polychromatic coherent light based on the first and second optical transitions of the reference sample (wherein, for example, at least two frequency harmonics of the polychromatic coherent light are stabilized based on a correlation between the wavelengths of the first and second clock transitions with respect to any environmental perturbations).

As discussed above, beams of the polychromatic coherent light, occupying the same spatial mode volume or separated in space, and having frequencies in the vicinity of the clock transitions of the reference sample, may be used to interrogate the resonances of the reference sample. Interrogation signals obtained using phase/frequency/amplitude spectroscopy or other techniques may then be used to stabilize the frequency harmonics of the light. If the harmonics belong to the same coherent frequency comb, the entire comb becomes stabilized using this procedure.

Detailed examples of the general method of FIG. 9 are provided above. See, e.g., the various methods described above and shown in the other figures where the stabilization features of FIG. 9 are exploited within optical atomic clocks or the like.

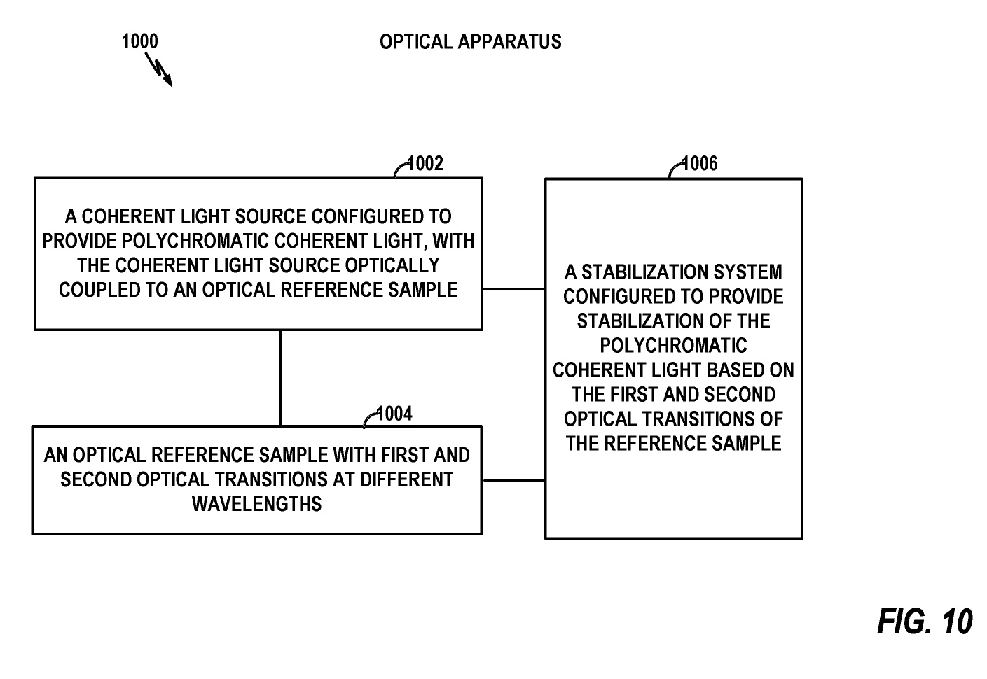

FIG. 10 summarizes general features of an exemplary apparatus 1000. Briefly, a coherent light source 1002 is configured to provide polychromatic coherent light, with the coherent light source optically coupled to an optical reference sample 1004 that has first and second optical transitions at different wavelengths. The apparatus 1000 also includes a stabilization system 1006 configured to provide stabilization of the polychromatic coherent light based on the first and second optical transitions of the reference sample (where, for example, the stabilization system 1006 is configured to provide stabilization of at least two frequency harmonics of the polychromatic coherent light based on a correlation between the wavelengths of the first and second clock transitions with respect to any environmental perturbations, as already explained).

Detailed examples of the general apparatus of FIG. 10 are provided above. See, e.g., the various embodiments described above and shown in the other figures where the stabilization system of FIG. 10 includes components such as a WGM resonator and various PDH sub-systems.

In at least some examples, means may be provided for performing the functions illustrated in FIGS. 9 and 10 and/or other functions illustrated or described herein. For example, the means may include one or more of: means, such as coherent light source 1002 of FIG. 10, for generating polychromatic coherent light using a coherent light source; means, such as optical coupler 212 of FIG. 2, for coupling a portion of the polychromatic coherent light into an optical reference sample, such as sample 1004 of FIG. 10, that has first and second optical transitions at different wavelengths; and means, such as stabilization system 1006 of FIG. 10, for stabilizing the polychromatic coherent light based on the first and second optical transitions of the reference sample.

Note that one or more of the components, steps, features, and/or functions illustrated in FIGS. 1, 2, 3, 4, 5, 6, 7, 8, 9, and/or 10 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, an aspect is an implementation or example. Reference in the specification to “an aspect,” “one aspect,” “some aspects,” “various aspects,” or “other aspects” means that a particular feature, structure, or characteristic described in connection with the aspects is included in at least some aspects, but not necessarily all aspects, of the present techniques. The various appearances of “an aspect,” “one aspect,” or “some aspects” are not necessarily all referring to the same aspects. Elements or aspects from an aspect can be combined with elements or aspects of another aspect.

The term “coupled” may mean that two or more elements are in direct physical or electrical contact. However, “coupled” may also mean that two or more elements are not in direct contact with each other, but yet still co-operate or interact with each other.

Not all components, features, structures, characteristics, etc. described and illustrated herein need be included in a particular aspect or aspects. If the specification states a component, feature, structure, or characteristic “may,” “might,” “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although some aspects have been described in reference to particular implementations, other implementations are possible. Additionally, the arrangement and/or order of elements or other features illustrated in the drawings and/or described herein need not be arranged in the particular way illustrated and described. Many other arrangements are possible according to some aspects.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Those of skill in the art would further appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An apparatus, comprising:
an optical reference sample with first and second optical transitions at different wavelengths;
a coherent light source configured to provide polychromatic coherent light, the coherent light source optically coupled to the optical reference sample; and
a stabilization system configured to provide stabilization of the polychromatic coherent light based on the first and second optical transitions of the reference sample.

2. The apparatus of claim 1, wherein the stabilization system is configured to provide stabilization of at least two frequency harmonics of the polychromatic coherent light based on a correlation between the wavelengths of the first and second optical transitions with respect to any environmental perturbations.

3. The apparatus of claim 1,
wherein the coherent light source includes a first coherent light source optically coupled to the optical reference sample and modulated by the first optical transition of the optical reference sample; and
wherein the apparatus includes a second coherent light source also coupled to the optical reference sample and modulated by the second optical transition of the optical reference sample.

4. The apparatus of claim 3, wherein the stabilization system includes an optical resonator optically coupled to the first coherent light source and configured to injection lock the first coherent light source, with the optical resonator controlled by a signal derived from a light beam from the second coherent light source.

5. The apparatus of claim 4, wherein the optical resonator comprises a whispering gallery mode (WGM) resonator.

6. The apparatus of claim 4, further comprising a transducer coupled to the optical resonator and configured to alter an optical property of the resonator, wherein the transducer is controlled by the signal derived from the light beam from the second coherent light source and configured to adjust a frequency of light coupled out of the resonator that provides the injection locking of the first coherent laser light source.

7. The apparatus of claim 4, further comprising an output component configured to output a clock signal generated from a beat within an optical comb light beam emerging from the optical resonator.

8. The apparatus of claim 3, wherein the stabilization system includes:
a first Pound-Drever-Hall (PDH) apparatus coupled to the first coherent light source and to the optical reference sample; and
a second PDH apparatus coupled to the second coherent light source and to the optical reference sample.

9. The apparatus of claim 1, wherein the optical reference sample comprises one or more of: an atomic vapor cell; an electrodynamic atomic trap; an optical atomic trap; and a solid state matrix doped with reference atoms or molecules.

10. The apparatus of claim 1, wherein the optical reference sample holds one or more rubidium atoms having the first (D₁) and the second (D₂) optical transitions.

11. A method, comprising:
generating polychromatic coherent light using a coherent light source;
coupling a portion of the polychromatic coherent light into an optical reference sample having first and second optical transitions at different wavelengths; and
stabilizing the polychromatic coherent light based on the first and second optical transitions of the reference sample.

12. The method of claim 11, wherein at least two frequency harmonics of the polychromatic coherent light are stabilized based on a correlation between the wavelengths of the first and second optical transitions with respect to any environmental perturbations.

13. The method of claim 11, wherein generating the polychromatic coherent light includes: (a) generating a first beam of coherent light using a first coherent light source; and (b) optically coupling a portion of the first beam into an optical resonator configured to injection lock the first coherent light source.

14. The method of claim 13, wherein optically coupling a portion of the first beam into an optical resonator comprises optically coupling the portion of the first beam into whispering gallery mode (WGM) resonator.

15. The method of claim 13, further comprising modulating the first beam using a first optical transition of the optical reference sample.

16. The method of claim 15, further comprising: (a) generating a second beam of coherent light using a second coherent light source; and (b) modulating the second beam using the second optical transition of the optical reference sample.

17. The method of claim 16, further comprising:
modulating at least one resonance frequency of the optical resonator using a signal derived from the second beam of coherent light; and
generating a clock signal from a beat within an optical comb light beam emerging from the optical resonator.

18. The method of claim 17, wherein the beat arises between at least two frequencies of the optical comb emerging from the optical resonator.

19. The method of claim 16, wherein modulating at least one resonance frequency of the optical resonator using a signal derived from the second beam comprises: applying the derived signal to a transducer that is coupled to the optical resonator and configured to alter an optical property of the optical resonator to adjust a frequency of light from the first coherent light source to stabilize the beat within the optical comb.

20. An apparatus, comprising:
means for generating polychromatic coherent light using a coherent light source;
means for coupling a portion of the polychromatic coherent light into an optical reference sample having first and second optical transitions at different wavelengths; and
means for stabilizing the polychromatic coherent light based on the first and second optical transitions of the reference sample.
